(19) United States
(12) Patent Application Publication
(10) Pub. No.: US 2025/0316558 A1
(43) Pub. Date: Oct. 9, 2025

(54) Transistor outline packaging structure and packaging method of transistor outline packaging structure

(71) Applicant: TONG HSING ELECTRONIC INDUSTRIES, LTD., Taoyuan City (TW)

(72) Inventor: Ting-An Yang, Taoyuan City (TW)

(73) Assignee: TONG HSING ELECTRONIC INDUSTRIES, LTD., Taoyuan City (TW)

(21) Appl. No.: 18/792,537

(22) Filed: Aug. 1, 2024

Related U.S. Application Data
(60) Provisional application No. 63/575,864, filed on Apr. 8, 2024.

(30) Foreign Application Priority Data
Jun. 7, 2024 (TW) 113121274

(51) Int. Cl. H01L 23/373; H01L 21/56; H01L 23/00; H01L 23/31; H01L 23/498; H01L 23/552; H01L 29/73; H01L 29/739; H01L 29/78

(52) U.S. Cl. CPC H01L 23/3735; H01L 23/3114; H01L 23/49811; H01L 23/49861; H01L 23/552; H01L 24/32; H01L 24/33; H01L 24/83; H01L 21/56; H01L 23/49866; H01L 2224/32253; H01L 2224/33181; H01L 2224/83986; H10D 10/00; H10D 12/411; H10D 30/60

(57) ABSTRACT

The invention provides a transistor outline (TO) packaging structure, which comprises a lower substrate, the lower substrate comprises a lower ceramic substrate, a lower conductive layer and a lower heat dissipation layer, an upper substrate, the upper substrate comprises an upper ceramic substrate, an upper conductive layer and an upper heat dissipation layer, a chip located between the lower substrate and the upper substrate, a molding material layer covering the chip and covering part of the lower substrate and the upper substrate, and a metal tab comprising an pin hole, wherein when from a cross-sectional view, a top surface of the upper substrate, a top surface of the metal tab, and a sidewall of the molding material layer form a stepped structure.

### CROSS REFERENCE TO RELATED APPLICATIONS

This application claims the benefit of U.S. Provisional Application No. 63/575, 864, filed on Apr. 8, 2024. The content of the application is incorporated herein by reference.

### BACKGROUND OF THE INVENTION

### 1. Field of the Invention

The invention relates to the field of semiconductor manufacturing, in particular to an improved transistor outline (TO) packaging structure and a packaging method of the transistor outline (TO) packaging structure, which have the advantages of double-sided heat dissipation, stable structure, good electromagnetic shielding efficiency and the like.

### 2. Description of the Prior Art

With the rapid development of power electronics technology, the requirement of power semiconductor density is higher and higher. Power semiconductor devices need to be able to operate at higher temperatures and frequencies while significantly reducing their size. This poses a more severe challenge to the heat dissipation management of power semiconductors.

Higher power density means higher calorific value, and higher current will also lead to higher calorific value. Effective thermal management can not only prevent catastrophic failure immediately, but also reduce the failure caused by thermal fatigue and high temperature accelerated material aging.

Power semiconductor heat dissipation technology is an important foundation for the development of power electronics technology. With the continuous improvement of the performance of power semiconductor devices, the heat dissipation technology of power semiconductor will also face greater challenges. It is of great significance to research and develop more efficient and reliable power semiconductor heat dissipation technology for promoting the development of power electronics technology.

For example, in the existing transistor outline (TO) family, such as TO-247, TO-220 and other package structures, all are common plastic packages used for power transistors and other power semiconductor devices. The transistor package structure family has the following characteristics: 1. High heat dissipation capacity: the transistor package structure family has large metal frames and large heat dissipation area, which can effectively dissipate the heat generated by the device, which makes it very suitable for high-power applications, such as power management, motor driving and LED lighting. 2. Low cost: the manufacturing process of transistor package structure family is simple and the cost is low, which makes it an economical choice in price-sensitive applications. 3. Easy assembly: the lead arrangement of the transistor package structure family is reasonable and easy to assemble on the printed circuit board, making it suitable for automatic production.

However, the current transistor package structure family has some shortcomings, one of which is the reliability problem. More specifically, stress is easy to occur between the metal frames and the heat sink of the transistor package structure family, which leads to package cracking or component damage, especially in high temperature or vibration environment.

Therefore, in order to improve the shortcomings of power semiconductors, especially for heat dissipation at high temperature, an improved structure must be proposed. In order to meet the challenge of power semiconductor heat dissipation, power semiconductor heat dissipation technology is also developing continuously. The main development trends include: the application of new heat dissipation materials, the design of new heat dissipation structure and the application of new heat dissipation methods.

### SUMMARY OF THE INVENTION

The invention provides a transistor outline (TO) packaging structure, which comprises a lower substrate, which comprises a lower ceramic substrate, a lower conductive layer and a lower heat dissipation layer, an upper substrate, which comprises an upper ceramic substrate, an upper conductive layer and an upper heat dissipation layer, a chip located between the lower substrate and the upper substrate, a molding material layer covering the chip and covering part of the lower substrate and the upper substrate, and a metal tab, which contains a hole, wherein a top surface of the upper substrate, a top surface of the metal tab and a sidewall of the molding material layer form a stepped structure from a sectional view.

The invention also provides a packaging method of transistor outline (TO) packaging structure, which comprises the following steps: providing a lower substrate, which comprises a lower ceramic substrate, a lower conductive layer and a lower heat dissipation layer, bonding a chip on the lower conductive layer of the lower substrate, bonding a metal tab to the lower substrate, wherein the metal tab partially exceeds the range of the lower substrate when viewed from a top view, providing an upper substrate, which comprises an upper ceramic substrate, an upper conductive layer and an upper heat dissipation layer, and bonding the upper substrate and the lower substrate face to face, so that the chip is located between the upper substrate and the lower substrate and is electrically connected with the upper substrate and the lower substrate.

To sum up, the traditional transistor package structure family is widely used in the field of power electronics, but its performance and reliability are limited by its single-sided heat dissipation, limited EMI (electromagnetic interference) shielding and low installation efficiency of heat sink. In order to overcome these limitations, the present invention provides an improved transistor outline (TO) package structure. Compared with the traditional transistor package structure family, it has the following advantages: 1. Double-sided heat dissipation: the top surface of the traditional transistor package structure family is made of epoxy resin, and the thermal conductivity of epoxy resin is far less than that of metal. The transistor package structure of the invention adopts double-sided heat dissipation design, and the top and bottom surfaces of the package are made of metal and ceramic substrates, such as AMB or DPC substrates. These substrates have large metal layers, which have excellent thermal conductivity and can effectively dissipate heat from both sides of the package. 2. Enhance thermal stress resistance: Double-sided heat dissipation design ensures more uniform heat distribution inside the package, and reduces thermal stress and unidirectional stress caused by uneven heating on both sides, thus reducing the risk of component damage. 3. Installation of double-sided heat sinks: The improved transistor package structure of the present invention has a metal tab extending outward as the installation point of the heat sink. These tabs eliminate the need for external clamps and provide a more reliable and durable heat sinks connection solution. 4. Effective EMI shielding: The metal substrates on both sides of the package act as a continuous metal layer to provide effective EMI shielding. This helps to reduce the EMI radiation generated by the package and protect the nearby electronic components from EMI interference.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

In order to make the following easier to understand, readers can refer to the drawings and their detailed descriptions at the same time when reading the present invention. Through the specific embodiments in the present specification and referring to the corresponding drawings, the specific embodiments of the present invention will be explained in detail, and the working principle of the specific embodiments of the present invention will be expounded. In addition, for the sake of clarity, the features in the drawings may not be drawn to the actual scale, so the dimensions of some features in some drawings may be deliberately enlarged or reduced.

FIG. 1, FIG. 2, FIG. 3, FIG. 4, FIG. 5, and FIG. 6 show schematic views of forming a transistor package structure according to a preferred embodiment of the present invention.

FIG. 7 is a schematic cross-sectional view of a transistor outline (TO) package structure according to an embodiment of the present invention.

FIG. 8 is a schematic cross-sectional view of the transistor outline (TO) package structure according to FIG. 7 after mounting a heat sink.

FIG. 9 is a schematic cross-sectional view of a transistor outline (TO) package structure according to another embodiment of the present invention.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the figures are only for illustration and the figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

Although the present invention uses the terms first, second, third, etc. to describe elements, components, regions, layers, and/or sections, it should be understood that such elements, components, regions, layers, and/or sections should not be limited by such terms. These terms are only used to distinguish one element, component, region, layer and/or block from another element, component, region, layer and/or block. They do not imply or represent any previous ordinal number of the element, nor do they represent the arrangement order of one element and another element, or the order of manufacturing methods. Therefore, the first element, component, region, layer or block discussed below can also be referred to as the second element, component, region, layer or block without departing from the specific embodiments of the present invention.

The term “about” or “substantially” mentioned in the present invention usually means within 20% of a given value or range, such as within 10%, or within 5%, or within 3%, or within 2%, or within 1%, or within 0.5%. It should be noted that the quantity provided in the specification is approximate, that is, the meaning of “about” or “substantially” can still be implied without specifying “about” or “substantially”.

The terms “coupling” and “electrical connection” mentioned in the present invention include any direct and indirect means of electrical connection. For example, if the first component is described as being coupled to the second component, it means that the first component can be directly electrically connected to the second component, or indirectly electrically connected to the second component through other devices or connecting means.

Although the invention of the present invention is described below by specific embodiments, the inventive principles of the present invention can also be applied to other embodiments. In addition, in order not to obscure the spirit of the present invention, specific details are omitted, and the omitted details are within the knowledge of those with ordinary knowledge in the technical field.

In the current technology, the package structure composed of multiple switches (such as transistors), such as full-bridge package or half-bridge package, is easy to generate a lot of heat when current passes through because it contains more electronic components. Therefore, these components pay special attention to heat dissipation efficiency. However, with the development of technology, the density of power semiconductors is getting higher and higher, and even in simple electronic units such as single switch package, there is a growing demand for improving the heat dissipation capacity.

In order to meet this challenge, the present invention provides a transistor outline (TO) package structure with double-sided heat dissipation function and stable structure. It is worth noting that the transistor outline (TO) package of the present invention is specially designed for the single switch package. The so-called transistor outline (TO) package means that only one switching element, such as a transistor, is included in the package structure. In addition, according to the design and application requirements of the specific switch, it can also include a diode.

Specifically, in the embodiment of the present invention described below, the chip only includes one transistor, such as MOSFET (metal-oxide-semiconductor field-effect transistor), BJT (bipolar junction transistor) or IGBT (insulated gate bipolar transistor), and does not include two or more transistors. In addition, the transistor outline (TO) package structure can also include a diode, which is used to protect the switching element from the reverse voltage, thus avoiding damage. This design ensures the efficient heat dissipation and stability of the single switch package.

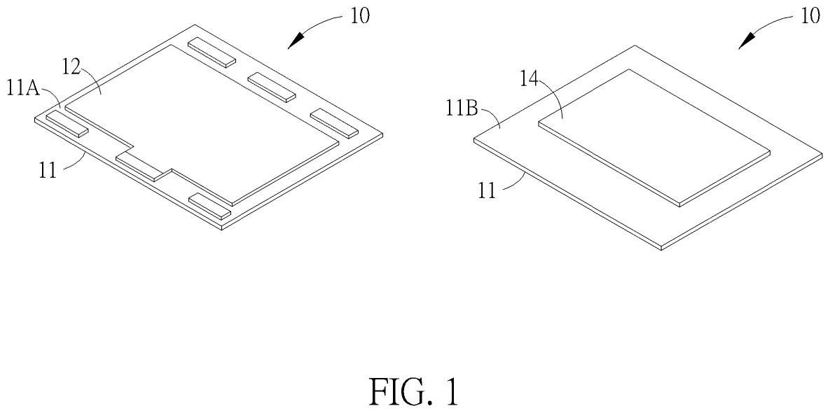

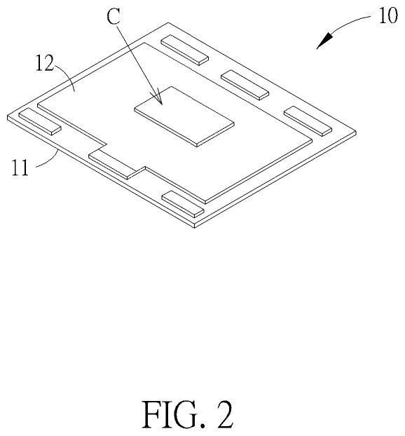

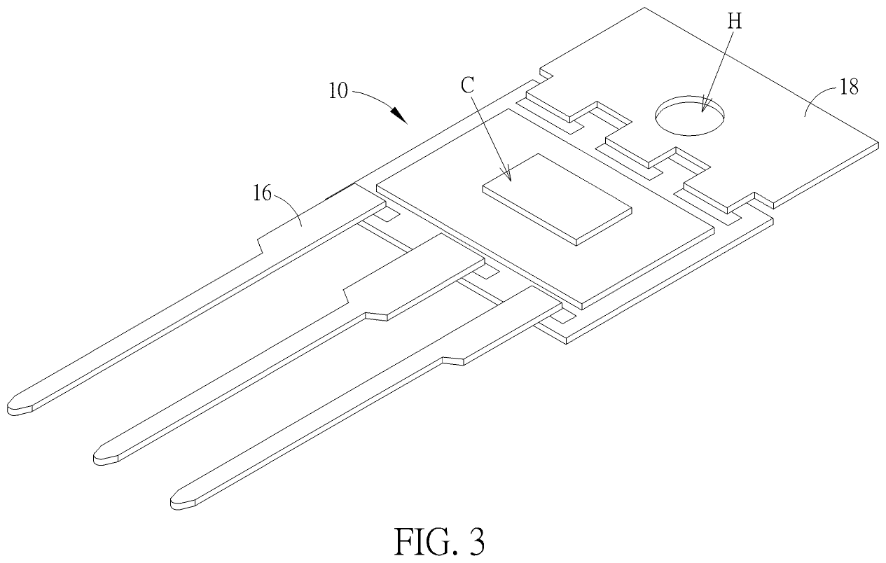

Therefore, according to the improved design of the present invention, the transistor outline (TO) package structure only includes one transistor and one diode. This design not only simplifies the package structure, but also significantly improves the heat dissipation efficiency through the design of double-sided heat dissipation, so that the single-switch package can still maintain good working state and reliability when meeting the demand of high power density. In a word, the transistor outline (TO) package structure of the present invention provides a stable and efficient solution to meet the requirements of modern power semiconductor applications while improving the heat dissipation capacity of components. In the following paragraphs, the steps of forming a transistor outline (TO) package structure will be described with reference to FIGS. 1 to 6.

FIG. 1 to FIG. 6 are schematic diagrams showing a transistor outline (TO) package structure formed according to a preferred embodiment of the present invention. As shown in FIG. 1, first, a lower substrate 10 is provided. The lower substrate 10 may include an AMB substrate (active metal polished substrate), a DPC substrate (direct plated copper) substrate or a DBC (direct bonded copper) substrate according to different manufacturing processes, which has a good heat dissipation effect. However, the present invention is not limited to the above specific substrate types.

The structure of the lower substrate 10 includes several parts: a lower conductive layer 12, a lower ceramic substrate 11 and a lower heat dissipation layer 14. The lower ceramic substrate 11 has a front surface 11A and a back surface 11B. The lower conductive layer 12 is disposed on the front surface 11A of the lower ceramic substrate 11, and the lower heat dissipation layer 14 is disposed on the back surface 11B of the lower ceramic substrate 11. The material of the conductive layer 12 and the heat dissipation layer 14 is, for example, copper, aluminum, gold, silver and other metals, but it is not limited to this. Copper is taken as an example in this embodiment. The main function of the conductive layer 12 is to connect the chips to be formed later, while the heat dissipation layer 14 is a large-area metal layer, which effectively dissipates the heat of the packaged semiconductor due to the excellent thermal conductivity of the metal material. For convenience of explanation, the left and right sides of FIG. 1 respectively show the structural schematic diagrams of the front surface and back surface of the lower substrate 10.

Next, as shown in FIG. 2, the chip C is mounted on the conductive layer 12 on the front surface 11A of the lower substrate 10. Chip C is a power semiconductor chip, in which chip C contains a transistor, such as MOSFET, BJT or IGBT. A large amount of heat energy will be generated during the operation of chip C, so an efficient heat dissipation mechanism is needed to maintain the stability of chip and prolong its service life. That is, as shown in FIG. 1 and FIG. 2, in order to dissipate heat more effectively, the conductive layer 12 is designed to connect the chip C so that its electrical signals can be conducted smoothly. The heat dissipation layer 14 uses its large area and excellent thermal conductivity to quickly conduct the heat generated during the operation of the chip C to avoid overheating.

In addition, the mounting of the chip C on the conductive layer 12 of the lower substrate 10 may include forming a connecting material layer such as metal pillar, conductive adhesive, solder, sintered silver, etc. on the conductive layer 12, and then mounting the chip C on the conductive layer 12. The connection material layer between the conductive layer 12 and the chip C is not drawn here for simplicity of the drawing, but it should be understood by those skilled in the art that the connection material layer exists.

As shown in FIG. 3, a lead frame 16 and a metal tab 18 are mounted on the lower substrate 10, wherein the function of the lead frame 16 is to connect the chip C with subsequent external components (such as a circuit board), so the lead frame 16 will be connected to the conductive layer 12 on the front surface 11A of the lower substrate 10, and the lead frame 16 is made of metal. That is to say, in the following steps, the electrical signal of the chip C will be transmitted to or received from the external circuit through the lead frame 16. In addition, in the transistor outline (TO) package structure of the present invention, a metal tab 18 is additionally installed when the lead frame 16 is installed, and the lead frame 16 and the metal tab 18 are respectively installed in two different directions of the lower substrate 10. The metal tab 18 has a hole H, for example, a circular hole. The purpose of installing the metal tab 18 here is to provide a mounting and fixing position for the heat sink when installing the heat sinks on the front and back sides of the transistor outline (TO) package structure in the subsequent process. More specifically, the hole H of the metal tab 18 can allow a screw to pass through, and the heat sinks mounted on the front and back sides of the transistor outline (TO) package structure can be fixed and locked with each other through the screw, so that the heat sinks can be firmly fixed on the transistor outline (TO) package structure. In this embodiment, the metal tab 18 is made of, for example, copper or aluminum to increase its thermal conductivity, but the present invention is not limited to this. In addition, although the metal tab 18 is connected to the lower substrate 10, it is not electrically connected to the chip C, so as to prevent the electrical signal of the chip C from being transmitted to the metal tab 18 and the subsequently formed heat sink, thus affecting the electrical property of the transistor outline (TO) package structure.

Next, as shown in FIG. 4, an upper substrate 20 is provided, wherein the upper substrate 20 has a structure similar to that of the lower substrate 10, and may include an AMB substrate (active metal polished substrate), a DPC substrate (direct plated copper substrate) or a DBC substrate (direct bonded copper substrate) according to the process mode, which has better heat dissipation effect. The present invention is not limited to the above specific substrate types.

The structure of the upper substrate 20 includes several parts: an upper conductive layer 22, an upper ceramic substrate 21 and an upper heat dissipation layer 24. The upper ceramic substrate 21 has a front surface 21A and a back surface 21B. The upper conductive layer 22 is disposed on the front 21A of the upper ceramic substrate 21, and the upper heat dissipation layer 24 is disposed on the back 21B of the upper ceramic substrate 21. The conductive layer 22 and the heat dissipation layer 24 are made of, for example, copper, aluminum, gold, silver and other metals, but not limited thereto. Copper is taken as an example in this embodiment. The main function of the conductive layer 22 is to connect the chip C, and the heat dissipation layer 24 is a large-area metal layer, which effectively dissipates the heat of the packaged semiconductor due to the excellent thermal conductivity of the metal material. For convenience of explanation, the left and right sides of FIG. 4 respectively show the structural schematic diagrams of the front surface and back surface of the upper substrate 20.

As shown in FIG. 5, a connecting material layer such as metal pillar, conductive adhesive, solder and sintered silver is formed on the conductive layer 22 of the upper substrate 20, and then the upper substrate 20 is turned over and bonded to it, so the chip C will be electrically connected to the conductive layer 22 of the upper substrate 20. The connecting material layer between the conductive layer 22 and the chip C is not drawn here for simplicity of the drawing, but it should be understood by those skilled in the art that the connecting material layer exists.

After the lower substrate 10 and the upper substrate 20 are connected, the chip C is electrically connected with the conductive layer 12 of the lower substrate 10 and the conductive layer 22 of the upper substrate 20 at the same time. Therefore, in the actual manufacturing process, the conductive layers 12 and 22 are designed on the upper and lower surfaces of the chip C, which means that the density of the conductive layer can be shared by the upper and lower substrates. Therefore, as far as the conductive layer of a single substrate is concerned, its line width and size can be designed to be looser, which is beneficial to reduce the difficulty of manufacturing process and assembly, and the larger area of the conductor layer is also helpful to the heat dissipation of the component.

Subsequently, the combined structure, including the lower substrate 10, the upper substrate 20, the chip C, the lead frame 16 and the metal tab 18, is put into a mold (not shown), and a mold filling step is carried out to form a molding material layer 30 covering part of the above structure. The material of the molding material layer 30 here is, for example, epoxy resin, but it is not limited thereto. After the mold filling step is completed, the transistor package structure 1 is completed, wherein the front and back structures of the transistor package structure 1 are shown in FIG. 6. As shown in FIG. 6, the molding material layer 30 exposes part of the heat dissipation layer 24 of the upper substrate 20 and part of the front surface of the metal tab 18 from the front surface (the upper diagram in FIG. 6), that is to say, part of the surface of the metal tab 18 is exposed from the front surface. In addition, because the top surface of the upper substrate 10 is higher than the top surface of the metal tab 18, the top surface of the upper substrate 10, the top surface of the metal tab 18 and part of the sidewall of the molding material layer 30 form a stepped structure (this part will be described in the following paragraphs). On the other hand, viewed from the back (the lower drawing in FIG. 6), the molding material layer 30 is the heat dissipation layer 14 of the lower substrate 10 which is partially exposed, but the molding material layer 30 covers the back of the metal tab 18. That is, when viewed from the back, the metal tab 18 is covered by the molding material layer 30, so that the metal tab 18 cannot be seen.

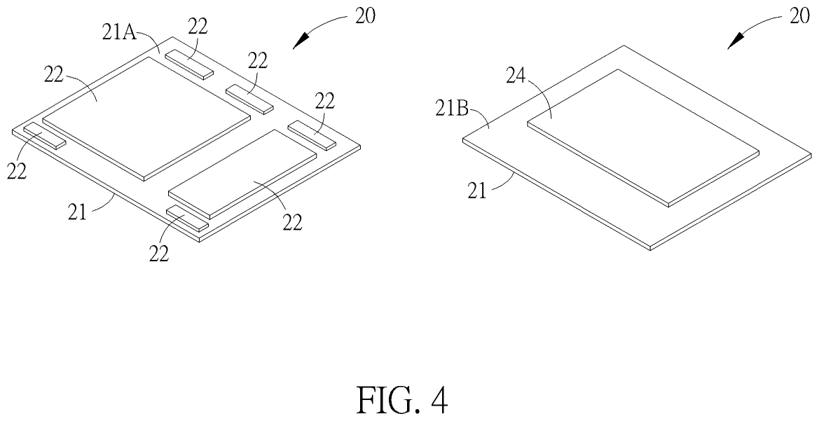

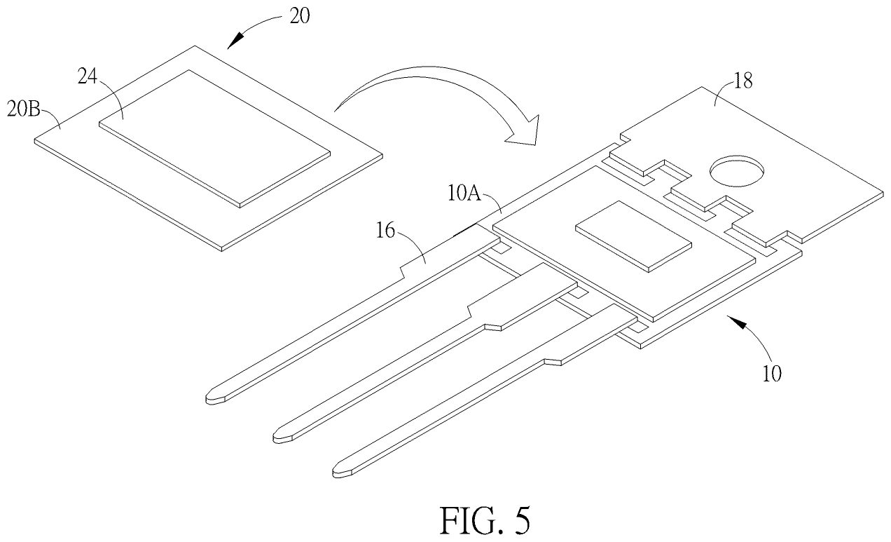

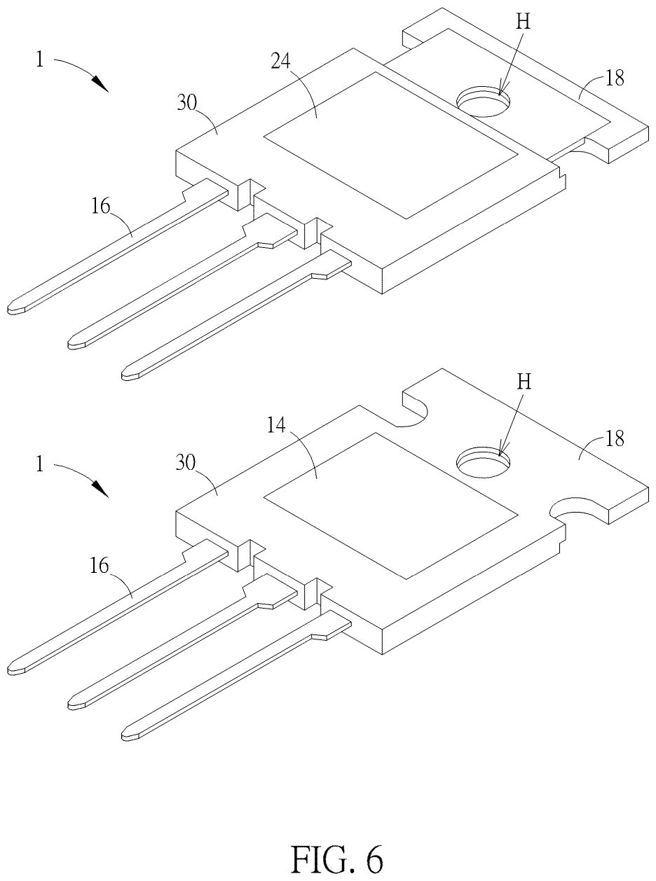

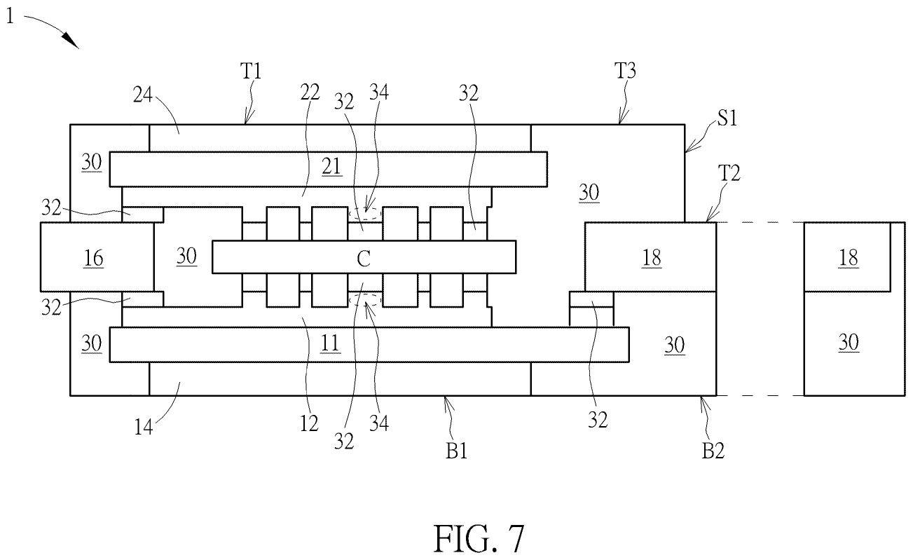

Reference can also be made to FIG. 7, which shows a schematic cross-sectional structure of a transistor outline (TO) package structure according to an embodiment of the present invention. In FIG. 7, some components can be shown with reference to the above-mentioned FIGS. 1 to 6, and these components are not repeated here. In addition, a part of the lead frame 16 is not completely drawn because it is beyond the figure display range, but those skilled in the art should be able to confirm the existence of the lead frame 16 without any doubt. It is worth noting that the cross-sectional view here shows the internal structure of the transistor package structure 1, in which the upper and lower ends of the chip C include connection material layers 32, such as conductive adhesive, solder, sintered silver, etc., but the present invention is not limited to this. In some embodiments, bumps 34 may be further included between the chip C and the conductive layer 12 and the conductive layer 22, and the bumps 34 are used to electrically connect the chip C with the conductive layer 12 and the conductive layer 22. In addition, the bump 34 may also have the functions of providing mechanical support to stabilize the structure, reducing parasitic capacitance and inductance, and improving impact and vibration resistance. The bumps 34 can be formed by, for example, electroplating, sputtering or chemical deposition.

In this embodiment, it can be more clearly seen from the cross-sectional structure in FIG. 7 that the front of the transistor outline (TO) package structure 1 has a stepped structure after the package material layer 30 is completed. As shown in FIG. 7, the surface of the upper heat dissipation layer 24 is defined as T1, the upper surface of the metal tab 18 is defined as the top surface T2, the surface of the molding material layer 30 which is flush with the top surface T1 of the upper substrate 20 is defined as the top surface T3, and the sidewall of the molding material layer 30 connecting the top surface T3 and the top surface T2 is defined as the sidewall S1, wherein the top surface T1 is parallel and aligned with the top surface T3, and the top surface T3 (or the top surface T1), the top surface T2 and the sidewall S1 together form the stepped structure. The top surface T1, the top surface T2 and the top surface T3 are parallel to each other, and in some embodiments, the sidewall S1 may be perpendicular to the top surface T3 or the top surface T2, but the present invention is not limited to this, that is, the sidewall S1 may not be perpendicular to the top surface T3 or the top surface T2.

In addition, as shown in FIG. 7, the bottom surface of the lower substrate 10 is defined as the bottom surface B1, and the bottom surface of the molding material layer 30 directly below the metal tab 18 is defined as the bottom surface B2, wherein in this embodiment, the bottom surface B1 and the bottom surface B2 are flush with each other. In other words, there is a part of the molding material layer 30 under the metal tab 18, which can support the metal tab 18 to avoid the structural instability caused by the suspension of the metal tab 18.

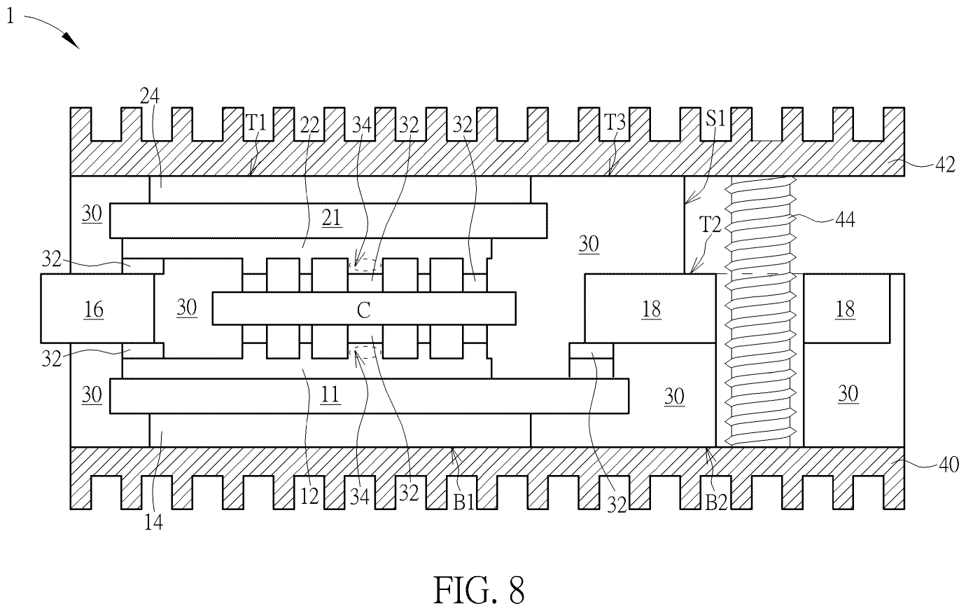

Next, please refer to FIG. 8, which shows the schematic cross-sectional structure of the transistor outline (TO) package structure according to FIG. 7 after mounting the heat sink. As shown in FIG. 8, a heat sink 40 is installed below the lower substrate 10, and a heat sink 42 is also installed above the upper substrate 20, wherein the heat sink 40 and the heat sink 42 are made of a plurality of parallel sheet structures, such as aluminum, copper or graphite, for transferring the heat energy generated by the chip to the air, but the present invention is not limited to this. In addition, the heat sink 40 and the heat sink 42 are fixed to each other by a screw 44, wherein the screw 44 passes through the hole H of the metal tab 18 and connects the heat sink 40 and the heat sink 42, so that the heat sink 40 and the heat sink 42 sandwich the transistor outline (TO) package structure 1.

As shown in FIG. 8, the lower heat sink 40 is completely attached to the bottom surface B1 of the lower substrate 10 and the bottom surface B2 of the adjacent molding material layer 30, so that the metal tab 18 is prevented from hanging, and the structure of the lower heat sink 40 is more stable. On the other hand, the upper heat sink 42 has a certain distance from the top surface T2 of the front surface of the metal tab 18, that is to say, the bottom surface of the heat sink 42 and the top surface T2 of the metal tab 18 are partially exposed to the air, so that the heat dissipation effect can be enhanced. To sum up, in the structure of the present invention, the heat dissipation effect of the transistor outline (TO) package structure can be improved, and at the same time, possible damage caused by structural fragility can be avoided.

In addition, thermal glue (not shown) may be included between the heat sink 40 and the lower substrate 10, and between the heat sink 42 and the upper substrate 20. The thermal glue, for example, is a colloid made of silicone, acrylate, epoxy resin or graphite, which serves to fix the heat sink and the package structure and increase the heat conduction effect, but the present invention is not limited to this. In some embodiments, since the heat sink 40 and the heat sink 42 have been fixed on the front and back sides of the transistor package structure by screws, it is also possible to omit the formation of thermal glue, which is also within the scope of the present invention.

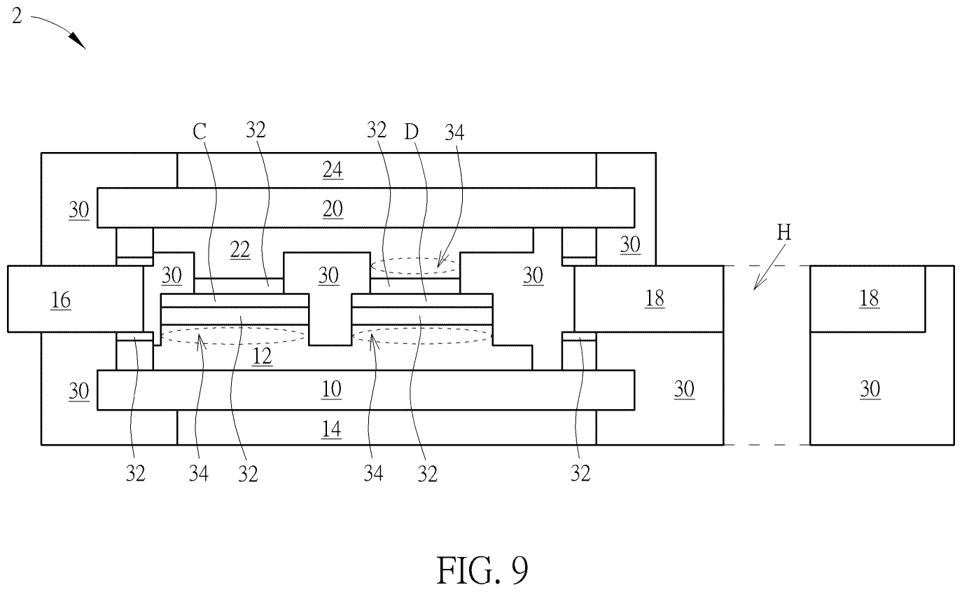

FIG. 9 is a schematic cross-sectional view of a transistor outline (TO) package structure according to another embodiment of the present invention. Most of the elements in FIG. 9 are the same as those shown in the above-mentioned FIG. 7, and these same elements are denoted by the same reference numerals, so as to facilitate mutual comparison among various embodiments. As shown in FIG. 9, in this embodiment, the inside of the transistor outline (TO) package structure 2 includes a diode D in addition to a chip C, wherein the diode D and the chip C are located between the lower substrate 10 and the upper substrate 20. The main function of diode D is to prevent the reverse current from damaging the circuit. Therefore, from the above-mentioned FIGS. 7 and 9, the transistor outline (TO) package structure of the present invention is suitable for single switch package, that is to say, in a package structure, one transistor is included, or one transistor and one diode are included, but no more than two transistors are included. Except for the diode D, most of the other components are the same as those described in the first embodiment, so they are not repeated here.

Based on the above description and drawings, a transistor outline (TO) package structure of the present invention (please refer to FIGS. 1 to 9) includes a lower substrate 10, which includes a lower ceramic substrate 11, a lower conductive layer 12 and a lower heat dissipation layer 14, an upper substrate 20, the upper substrate 20 comprises an upper ceramic substrate 21, an upper conductive layer 22 and an upper heat dissipation layer 24, a chip C located between the lower substrate 10 and the upper substrate 20, a molding material layer 30, a metal tab 18 covering part of the lower substrate 10 and the upper substrate 20, wherein the metal tab 18 contains a hole H, and in a cross-sectional view, a top surface of the upper substrate 20 (i.e., the top surface Tl of the upper heat dissipation layer 24), a top surface T2 of the metal tab 18 and a sidewall S1 of the molding material layer 30 form a stepped structure.

In some embodiments of the present invention, the top surface of the upper substrate 10 (that is, the top surface Tl of the upper heat dissipation layer 24) is parallel to the top surface T2 of the metal tab 18, and the sidewall S1 of the molding material layer 30 connects the top surface T1 of the upper substrate 10 and the top surface T2 of the metal tab 18.

In some embodiments of the present invention, a part of the molding material layer 30 is located directly below the metal tab 18 and covers a bottom surface of the metal tab 18, but a part of the top surface T2 of the metal tab 18 is not covered by the molding material layer 30. In other words, as seen from FIG. 7, the lower surface of the metal tab 18 is covered by the molding material layer 30.

In some embodiments of the present invention, a part of the molding material layer 30 is located directly below the metal tab 18 when viewed from the cross section, and the molding material layer 30 located directly below the metal tab 18 has a bottom surface B2.

In some embodiments of the present invention, the bottom surface B2 of the molding material layer 30 directly below the metal tab 18, a bottom surface B1 of the lower substrate 10 is flushed with the bottom surface B2 of the molding material layer 30.

In some embodiments of the present invention, the metal tab 18 has a hole H when viewed from a top view, and the metal tab 18 does not overlap with the upper substrate 20 or the lower substrate 10.

In some embodiments of the present invention, the metal tab 18 is made of copper, aluminum, gold and silver.

In some embodiments of the present invention, the materials of the lower heat dissipation layer 14 of the lower substrate 10 and the upper heat dissipation layer 24 of the upper substrate 20 include copper foil.

In some embodiments of the present invention, it further includes an upper heat sink 42 and a lower heat sink 40. The upper heat sink 42 contacts the upper heat dissipation layer 24 of the upper substrate 20, and the lower heat sink 40 contacts the lower heat dissipation layer 14 of the lower substrate 10.

In some embodiments of the present invention, the upper heat sink 42 and the lower heat sink 40 are connected with each other by a screw 44, and the screw 44 passes through the hole H of the metal tab 18.

In some embodiments of the present invention, the transistor outline (TO) package structure 1 only includes a chip C, and the chip C includes a transistor, the transistor is an IGBT, a MOSFET or a BJT, and does not include more than two transistors.

The invention also provides a packaging method of transistor outline (TO) packaging structure, which comprises providing a lower substrate 10, which comprises a lower ceramic substrate 11, a lower conductive layer 12 and a lower heat dissipation layer 14, bonding a chip C to the lower conductive layer 12 of the lower substrate 10, and bonding a metal tab 18 to the lower substrate 10, wherein from a top view, the metal tab 18 partially exceeds the range of the lower substrate 10, and provides an upper substrate 20, which includes an upper ceramic substrate 21, an upper conductive layer 22 and an upper heat dissipation layer 24, and bonds the upper substrate 20 and the lower substrate 10 face to face, so that the chip C is located between and electrically connected with the upper substrate 20 and the lower substrate 10.

In some embodiments of the present invention, a mold filling step is further included, in which the bonded upper substrate 20 and lower substrate 10 are placed in a mold, and a molding material is poured into the mold to form a molding material layer 30 covering part of the upper substrate 20, lower substrate 10 and metal tab 18 (refer to the step description shown in FIG. 6).

To sum up, the traditional transistor package structure family is widely used in the field of power electronics, but its performance and reliability are limited by its single-sided heat dissipation, limited EMI (electromagnetic interference) shielding and low installation efficiency of heat sink. In order to overcome these limitations, the present invention provides an improved transistor outline (TO) package structure. Compared with the traditional transistor package structure family, it has the following advantages: 1. Double-sided heat dissipation: the top surface of the traditional transistor package structure family is made of epoxy resin, and the thermal conductivity of epoxy resin is far less than that of metal. The transistor package structure of the invention adopts double-sided heat dissipation design, and the top and bottom surfaces of the package are made of metal and ceramic substrates, such as AMB or DPC substrates. These substrates have large metal layers, which have excellent thermal conductivity and can effectively dissipate heat from both sides of the package. 2. Enhance thermal stress resistance: Double-sided heat dissipation design ensures more uniform heat distribution inside the package, and reduces thermal stress and unidirectional stress caused by uneven heating on both sides, thus reducing the risk of component damage. 3. Installation of double-sided heat sinks: The improved transistor package structure of the present invention has a metal tab extending outward as the installation point of the heat sink. These tabs eliminate the need for external clamps and provide a more reliable and durable heat sinks connection solution. 4. Effective EMI shielding: The metal substrates on both sides of the package act as a continuous metal layer to provide effective EMI shielding. This helps to reduce the EMI radiation generated by the package and protect the nearby electronic components from EMI interference.

The transistor outline (TO) package structure of the present invention is particularly suitable for applications requiring high heat dissipation performance, thermal reliability and EMI shielding, such as power converters, motor drivers, power suppliers, automotive lighting systems, electric vehicle power systems, advanced driver assistance systems (ADAS), industrial motors, variable speed drivers, uninterruptible power supplies (UPS), power amplifiers, base stations and repeaters, etc., but not limited thereto.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A transistor outline (TO) package structure, comprising:
a lower substrate, which comprises a lower ceramic substrate, a lower conductive layer and a lower heat dissipation layer;
an upper substrate, which comprises an upper ceramic substrate, an upper conductive layer and an upper heat dissipation layer;
a chip located between the lower substrate and the upper substrate;
a molding material layer covering the chip and covering part of the lower substrate and the upper substrate; and
a metal tab, which contains a hole, wherein a top surface of the upper substrate, a top surface of the metal tab and a sidewall of the molding material layer form a stepped structure from a sectional view.

2. The transistor outline (TO) package structure according to claim 1, wherein the top surface of the upper substrate is parallel to the top surface of the metal tab when viewed from the cross section, and the sidewall of the molding material layer connects the top surface of the upper substrate and the top surface of the metal tab.

3. The transistor outline (TO) package structure according to claim 1, wherein when viewed from the cross section, part of the molding material layer is located directly below the metal tab and covers a bottom surface of the metal tab, but part of the top surface of the metal tab is not covered by the molding material layer.

4. The transistor outline (TO) package structure according to claim 3, wherein when viewed from the cross section, part of the molding material layer is located directly below the metal tab, and the molding material layer directly below the metal tab has a bottom surface.

5. The transistor outline (TO) package structure according to claim 4, wherein the bottom surface of the molding material layer directly below the metal tab is flush with a bottom surface of the lower substrate.

6. The transistor outline (TO) package structure according to claim 1, wherein the hole of the metal tab is a circle hole when viewed from a top view, and the metal tab does not overlap with the upper substrate or the lower substrate.

7. The transistor outline (TO) package structure according to claim 1, wherein the metal tab comprises copper, aluminum, gold and silver.

8. The transistor outline (TO) package structure according to claim 1, wherein the lower heat dissipation layer of the lower substrate and the upper heat dissipation layer of the upper substrate are made of copper foil.

9. The transistor outline (TO) package structure according to claim 1, further comprising an upper heat sink and a lower heat sink, wherein the upper heat sink contacts the upper heat dissipation layer of the upper substrate and the lower heat sink contacts the lower heat dissipation layer of the lower substrate.

10. The transistor outline (TO) package structure according to claim 9, wherein the upper heat sink and the lower heat sink are connected with each other by a screw, and the screw passes through the hole of the metal tab.

11. The transistor outline (TO) package structure according to claim 1, wherein the transistor outline package structure only includes a chip, and the chip includes a transistor, the transistor is an IGBT, a MOSFET or a BJT, and does not include more than two transistors.

12. A packaging method of transistor outline (TO) packaging structure, comprising:
providing a lower substrate, which comprises a lower ceramic substrate, a lower conductive layer and a lower heat dissipation layer;
bonding a chip on the lower conductive layer of the lower substrate;
bonding a metal tab to the lower substrate, wherein the metal tab partially exceeds the range of the lower substrate when viewed from a top view;
providing an upper substrate, which comprises an upper ceramic substrate, an upper conductive layer and an upper heat dissipation layer; and
bonding the upper substrate and the lower substrate face to face, so that the chip is located between the upper substrate and the lower substrate and is electrically connected with the upper substrate and the lower substrate.

13. The packaging method of transistor outline (TO) package structure according to claim 12, further comprising:
performing a mold filling step, placing the bonded upper substrate and the bonded lower substrate in a mold, and filling a molding material into the mold to form a molding material layer covering part of the upper substrate, the lower substrate and the metal tab.

14. The packaging method of transistor outline (TO) package structure according to claim 13, wherein a top surface of the upper substrate, a top surface of the metal tab and a sidewall of the molding material layer form a stepped structure from a sectional view.

15. The packaging method of transistor outline (TO) package structure according to claim 13, wherein the top surface of the upper substrate is parallel to the top surface of the metal tab, and the sidewall of the molding material layer connects the top surface of the upper substrate and the top surface of the metal tab.

16. The packaging method of transistor outline (TO) package structure according to claim 13, wherein when viewed from the cross section, part of the molding material layer is located directly below the metal tab and covers a bottom surface of the metal tab, but part of the top surface of the metal tab is not covered by the molding material layer.

17. The packaging method of transistor outline (TO) package structure according to claim 16, wherein when viewed from the cross section, part of the molding material layer is located directly below the metal tab, wherein the molding material layer directly below the metal tab has a bottom surface, and the bottom surface of the molding material layer is flush with a bottom surface of the lower substrate.

18. The packaging method of transistor outline (TO) package structure according to claim 12, further comprising forming an upper heat sink and a lower heat sink, wherein the upper heat sink contacts the upper heat dissipation layer of the upper substrate, and the lower heat sink contacts the lower heat dissipation layer of the lower substrate.

19. The packaging method of transistor outline (TO) package structure according to claim 18, wherein the upper heat sink and the lower heat sink are connected with each other by a screw, and the screw passes through the hole of the metal tab.

20. The packaging method of transistor outline (TO) package structure according to claim 12, wherein the transistor outline packaging structure only includes a chip, and the chip includes a transistor, the transistor is an IGBT, a MOSFET or a BJT, and does not include more than two transistors.
